(19) United States
(12) Patent Application Publication
(10) Pub. No.: US 2012/0288122 A1
(43) Pub. Date: Nov. 15, 2012

(54) METHOD AND A SYSTEM FOR AN ACOUSTIC CURTAIN THAT REVEALS AND CLOSES A SOUND SCENE

(75) Inventor: Morten Lydolf, Holstebro (DK)

(73) Assignee: BANG & OLUFSEN A/S, Struer (DK)

(21) Appl. No.: 13/519,242

(22) PCT Filed: Dec. 6, 2010
(86) PCT No.: PCT/EP2010/068989

§ 371 Date: Jun. 26, 2012

(30) Foreign Application Priority Data
Jan. 15, 2010 (DK) PA 2010 00031

(51) Int. Cl. H03G 3/00

(52) U.S. Cl. 381/107

(57) ABSTRACT

A system and a method of operating the system which has at least two groups of sound providers, where the virtual position of the second group of sound providers is moved from the position of the first group of speakers to that of the second group of speakers. Also a third group of speakers may be used, the position of which is virtually moved from that of the first group via the position of the second group to that of the third group of speakers.

The present invention relates to a method of altering between different audio providing modes and in particular to the use of the altering method for initiating or ending providing of audio.

Presently, audio systems adapted to provide the audio in different modes is quite widespread and usual. Historically, the two audio modes possible are mono and stereo, but nowadays, playback systems adapted to also multichannel audio using 3, 4, 5, 6, 7 or more speakers, such as using the so-called 3.0, 4.0, 5.1 or 7.1 modes in which 3, 4, 6 or 8 speakers are used. For such systems, rules or guidelines exist for the position thereof in order to obtain the desired surround sound effect.

Audio systems may be seen in e.g. WO2008/142651, WO2008/097625, US2002/0172379, U.S. Pat. No. 3,757,046, and US2005/0047614.

When initiating the providing of audio, for example, it is desired to have this initiation performed in a gentle manner in which one is informed or reminded of the constellation of the audio providing system.

The present invention relates to a solution thereto and, in a first aspect, relates to a method of operating a system comprising a first and a second group of sound providers, the first and second groups being non-overlapping, and a controlling unit adapted to provide a host audio signal for each of the sound providers,

the method comprising:
during a first period of time, the controlling unit generating an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, the controlling unit simultaneously:
generating the individual first signal for each of the sound providers of the first group,
generating an individual second signal for each of the selected sound provider(s) of the second group, at least one of the second signal(s) being based on at least the host audio signal for the pertaining sound provider of the second group,
   wherein a ratio between:
the signal strength or intensity, in the at least one second signal, of the host audio signal for the pertaining sound provider of the second group and
the signal strength or intensity, in the at least one first signal, of the host audio signal for the selected sound provider(s) of the second group
   increases during the second period of time.

In this context, different types of systems may be used for outputting audio. Different audio playback modes exist using different sound providers or different numbers or positions of sound providers. The historic playback modes are mono and stereo, and more recent playback modes are the surround sound modes using three or more sound providers. A mono signal may be provided by a single sound provider which is then usually positioned right in front of the listener or a listening position or may be provided by multiple sound providers receiving the same audio signal. Stereo is provided using two sound providers positioned in front of but to the two sides of the listening position, where the two sound providers receive different audio signals. As to the surround sound modes, a number thereof exist, such as the 3.0, 4.0, 5.1, 7.1 or 7.2 modes in which 3, 4, 6 (incl. a subwoofer), 8 (incl. a subwoofer) and 9 (incl. 2 subwoofers) sound providers are used. Usually, in surround sound modes, a central sound provider is positioned in front of the listening position and two in front of and to the sides of the central sound provider. Then, two sound providers may be provided to the side but behind the listening position and sound providers may be provided at the sides of the listening position and between the listening position and the central sound provider. Finally, one or more subwoofers may be used to boost the lowest frequencies.

Presently, a first and a second group of sound providers are used. The groups are non-overlapping meaning that no sound provider is a member of both groups. A group may hold 1, 2, 3 or more sound providers.

Usually, the two groups are populated by sound providers in selected positions in relation to each other. In one situation, the sound providers are provided around a listening position from which a listening direction is defined. In this situation, the sound providers of the first group usually are positioned further along the listening direction than the sound providers of the second group. Further groups may be defined which are also positioned either further along the listening position, along the opposite direction thereto or maybe further to a central position than the sound providers of other groups.

Also, the groups may be subdivided along the listening direction to have sound providers for the listener's right and left ear or side. The sound providers may be operated in the same manner to the right and left side, even though the signals sent to such loudspeakers may differ.

Naturally, the signals fed to the sound providers will usually relate to the same overall audio signal, such as a song or music, but will differ in order to give the stereo or surround sound effect. The original or provided audio information or file may comprise the individual host signals for each sound provider, or such individual host signals may be derived using known methods. In a typical situation, the original signal will comprise a front left and a front right signal (stereo signal), from which a central channel may be derived by summing (mono signal), and left/right back channels may be derived by emphasizing the differences between the front left/right channels.

Thus, the mono signal for a centre channel may form the first group. The original left and right front channels may unamended thus be the second group, whereas a back left and right signal may be derived from the original front left and right signals in the standard manner. These back channels may then be group three. Thus, the three additional signals are generated from the two original tracks, but as this generation or the ratio of the contents of the two tracks in the individual signals are constant, these 5 channels will then be the host signals.

In addition, the left speakers and the right speakers may be treated similarly but with different signals. Thus, the front left and back left host signals may be fed only to the left speakers (and the central speaker), whereas the front right and back right host signals may be fed only to the right speakers (and the central speaker). Thus, certain selected sound providers of the groups may be forming a sub-group and other selected sound providers may be another sub-group within which signals are not mixed.

It is noted that the same audio signal may be fed to more than one sound provider. In one situation, different sound providers have different properties, such as one outputting only or mainly the lower frequencies and another only or mainly the higher frequencies, such that they together act like a full range sound provider. In another situation, a higher sound pressure or intensity is desired, whereby more sound providers may be used. Preferably, the sound providers receiving the same audio signal are positioned at or close to each other.

The system comprises a controlling unit adapted to provide the host audio signals for the sound providers. This controlling unit may also comprise means for receiving (aerial, network, CD/DVD/Blueray reader, MP3/4 player or the like) the audio signal(s) and/or generate these if desired. As described, an audio signal received or provided may be processed in order to generate all required host audio signals.

In this respect, the host audio signals will typically be those provided for the sound providers (typically before amplification) during normal operation. Thus, the host signals will be generated for each sound provider so as to generate the surround effects desired.

Naturally, as all audio signal processing will usually be performed in a single Digital Signal Processor (DSP), the host signals need not be generated before the mixing thereof is performed to generate the at least one first, second and optionally third signals during the first, second and later on third periods of time. After the first, second and optionally third (or how may periods of time is desired), the host signals are preferably output for the sound providers.

In the first signals generated during the first, second and optionally third periods of time, the ratios will differ to generate a surround sound effect other that of normal operation.

During the first period of time, the controlling unit generates an individual first signal to each of the sound provider(s) of the first group. The second sound provider(s) preferably do not output sound (do not receive an audio signal).

It is noted that the audio signals may be fed to the sound providers as generated by the controlling unit but are preferably amplified prior to feeding to the sound providers. As will be described below, this amplification may be the same for all sound providers as is usual in volume controlling of audio.

During the first period of time, at least one of the first signal(s) is based on at least the host audio signal for the pertaining sound provider of the first group and the host audio signal for one or more selected sound provider(s) of the second group. Depending on the actual effect sought for, the host audio signal for a single sound provider of the second group may be used, or those for multiple sound providers may be used.

During the first period of time and in the at least one first signal, a signal strength or intensity of the host audio signal for the pertaining sound provider of the first group and a signal strength or intensity of the host audio signal for the sound provider(s) of the second group may increase. If the at least one first signal has no other components, which may be the case, the signal strength of this signal or intensity output will then increase during the first period of time. This may be when e.g. turning on the system.

Subsequent to the first period of time, a second period of time is defined wherein the controlling unit simultaneously alters the contents of the at least one first signal and the signal(s) for the selected sound provider(s) of the second group.

During the second period of time, which preferably starts immediately after the first period of time ends, the signal strength or intensity, in the at least one first signal, of the host audio signal for the pertaining sound provider of the first group may increase during the second period of time in order to e.g. reach a target signal strength or loudness.

Also, at least one of the second signal(s) is based on at least the host audio signal for the pertaining sound provider of the second group, a signal strength or intensity of this host audio signal for the pertaining sound provider of the second group increases.

Thus, when the at least one of the first signal and the at least one second signal are fed to the pertaining sound providers, the position of the sound provider of the second group will virtually (sound as if) move from the position of the sound provider of the first group toward the position of the sound provider of the second group. If the signal strength or intensity of the host audio signal for the sound provider(s) of the second group in the at least one first signal decreases to zero in the second period of time, the perceived position of the sound provider of the second group will be the actual position of that sound provider.

It is noted that an increase or decrease of a signal strength or loudness or the altering of a ratio may be performed as a constant or an intermittent decrease/increase/altering during the period of time. The decrease/increase/altering may be constant in the sense that the increase is constant during the period of time. Alternatively, variations may be allowed so that e.g. an increase does not have a portion decreasing but may be allowed to remain constant for a portion of the period of time.

In a preferred embodiment, the system comprises also a third group of sound providers, the first, second and third groups being non-overlapping, wherein:

during the first period of time, the at least one of the first signal(s) is based also the host audio signal for one or more selected sound provider(s) of the third group,
during the second period of time:
the signal strength or intensity, in the at least one first signal, of the host audio signal for the selected sound provider(s) of the third group decreases,
the at least one of the second signal(s) is based also on the host audio signal for one or more of the selected sound provider(s) of the third group, a signal strength or intensity, in the at least one second signal, of the host audio signal for the pertaining sound provider(s) of the third group increasing during the second period of time and
   during a third period of time, subsequently to the second period of time, the controlling unit simultaneously:
generating the individual second signal for each of the sound providers of the second group, the signal strength or intensity, in the at least one second signal, of the host audio signal for the pertaining sound provider(s) of the third group decreasing during the third period of time and
generating an individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group, increasing during the third period of time.

As indicated above, during the first period, a signal strength or intensity, in the at least one first signal, of the host audio signal for the sound provider(s) of the third group may increase during the first period of time to “turn up the volume”.

Thus, similarly to the evolving of the at least one second signal, the signal for the sound provider of the third group is, during the first period of time, part of the signal for the sound provider of the first group, where it is virtually at least partly shifted to the at least one second signal during the second period of time. In this embodiment, this signal is subsequently shifted at least partly, but preferably fully, to the at least one third signal during the third period of time.

Thus, virtually, in addition to the virtual re-positioning of the sound provider of the second group during the second period of time, the sound provider of the third group is re-positioned in the same manner during the second period of time and is further re-positioned toward the actual position of the sound provider of the third group during the third period of time.

In one embodiment, the controlling unit generates, during the second period of time, the individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group increasing during the second period of time.

Alternatively, the at least one third signal is very weak if not zero during the first and second periods of time.

Preferably, the at least one second signal and at least one third signal have at least substantially no part of the host signal for the pertaining sound provider of the first group.

During the third period of time, which preferably starts immediately after the second period of time ends, the at least one second signal may be constant or may have an increasing signal strength or intensity of the host audio signal for that sound provider. In the first situation, the virtual sound provider of the second group will obtain its final position during the second period of time, whereas in the second situation, it may obtain this position during the third period of time. Thus, the sound providers of the second group may be allowed to take up their final positions before or at the same time as the sound providers of the third group.

Another aspect of the invention relates to a method of operating a system comprising a first and a second group of sound providers, the first and second groups being non-overlapping, and a controlling unit adapted to provide a host audio signal for each of the sound providers,

the method comprising:
during a first period of time, the controlling unit generating an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, the controlling unit simultaneously:
generating the individual first signal for each of the sound providers of the first group,
generating an individual second signal for each of the selected sound provider(s) of the second group, at least one of the second signal(s) being based on at least the host audio signal for the pertaining sound provider of the second group,
   wherein a ratio between:
the signal strength or intensity, in the at least one second signal, of the host audio signal for the pertaining sound provider of the second group and
the signal strength or intensity, in the at least one first signal, of the host audio signal for the selected sound provider(s) of the second group
   increases during the second period of time.

Again, it may be desired to have a signal strength or intensity, in the at least one first signal, of the host audio signal for the pertaining sound provider of the first group and a signal strength or intensity of the host audio signal for the sound provider(s) of the second group increase during the first period of time,

Also, it may be desired to have the signal strength or intensity, in the at least one first signal, of the host audio signal for the pertaining sound provider of the first group increase during the second period of time.

The above definitions and descriptions of terms of the claims are equally applicable to the present aspect of the invention.

Presently, the ratio may be determined on the basis of a quantification of the signal strength or signal intensity. An alternative is to use the actual sound output from the sound providers, as the virtual position(s) of the selected sound provider(s) of the second group is determined by the physical positions of the sound providers receiving the at least one first and at least one second signals and the ratio between the sound pressure/intensity or loudness output by these sound providers. When this ratio increases, the experienced or virtual position of the sound provider(s) receiving the host audio signal will approach the actual position of the sound provider(s) receiving the at least one second signal.

In this relation, loudness may be established or determined as defined in ISO 226:2003.

Thus, again, the second period of time will provide signals increasing the surround sound providing of the system in that the sound during the first period of time when, as is preferred, no signals are generated for the sound providers of the second group, will be coming from the sound providers of the first group but will, during the second period of time, virtually move the sound providers (at least that/those receiving the at least one second signal) from the positions of the sound providers of the first group toward the actual positions of the sound providers of the second group. This gives a listener, when the signals are fed to the sound providers, the experience that the second sound providers are repositioned or moved to their intended or physical positions.

In a preferred embodiment, the system comprises also a third group of sound providers, the first, second and third groups being non-overlapping, wherein:

during the first period of time, the at least one of the first signal(s) is based also the host audio signal for one or more selected sound provider(s) of the third group,
during the second period of time, the at least one second signal is based also on the host audio signal for one or more of the selected sound provider(s) of the third group,
wherein a ratio between:
the signal strength or intensity, in the at least one second signal, of the host audio signal for the selected sound provider(s) of the third group and
the signal strength or intensity, in the at least one first signal, of the host audio signal for the selected sound provider(s) of the third group
   increases during the second period of time,
   during a third period of time, subsequently to the second period of time, the controlling unit simultaneously:
generates the individual second signal(s), at least one of the second signal(s) being based also on and one or more of the selected the host audio signal(s) for the sound provider(s) of the third group, and
generating an individual third signal for each of the selected sound provider(s) of the third group, at least one of the third signal(s) being based on at least the host audio signal for the pertaining sound provider of the third group,
   wherein a ratio of:
the signal strength or intensity, in the at least one third signal, of the host audio signal for the selected sound provider(s) of the third group and
a signal strength or intensity, in the at least one second signal, of the host audio signal for the pertaining sound provider of the third group
   increases during the third period of time.

It may be desired to have a signal strength or intensity, in the at least one first signal, of the host audio signal for the sound provider(s) of the third group increase during the first period of time.

In one embodiment, during the second period of time, the controlling unit also generates the individual third signal(s) for each of the selected sound provider(s) of the third group, at least one of the third signal(s) being based on at least the host audio signal for the pertaining sound provider of the third group,

wherein a ratio between:
the signal strength or intensity, in the at least one third signal, of the host audio signal for the pertaining sound provider of the third group and
the signal strength or intensity, in the at least one first signal, of the host audio signal for the selected sound provider(s) of the third group
   increases during the third period of time.

Alternatively, no signal is output to the sound providers of the third group in the first and second periods of time.

In one embodiment of both aspects, the method further comprises the step of the controlling unit receiving a volume indication, wherein, during the first, second and optionally third periods of time, the first, second and optionally third signals are amplified by a factor relating to the volume indication.

Naturally, the volume indication may be a setting definable or variable by a user or listener. This indication may be varied or altered at any point in time during operation. Usually, the volume indication instructs the audio system which overall loudness/sound pressure or intensity of the combined audio output by all sound providers is desired. The volume indication may be absolute and relate to an absolute quantification of the loudness/sound pressure/intensity or may be relative so that an amplifier or amplification of the audio signals or generating the audio signals is only altered, when the volume indication is altered. Thus, if the sound is too low, the volume indication may be increased, resulting in a higher intensity/signal strength output of the controller and thus a higher loudness or sound intensity from the individual sound providers.

This is standard operation for audio systems when operating. However, if the volume is turned up in e.g. the second period of time of the first aspect of the invention, the output signal may actually see an increase in the signal when output to the sound provider of the second group, even when this is desired reduced. However, as the signals for the sound providers of the second group are also amplified, the virtual re-positioning of the sound providers of the second group still takes place.

The above volume indication is not the only user-definable input which may alter the individual intensities or signal strengths. Also, a difference in left/right balance (increasing or decreasing all intensities or signal strengths to sound providers in the right/left side) may affect the final first/second/third intensities/signal strengths output.

Preferably, the controlling unit, during the second, and optionally also third, period of time, outputs the intensities or signal strengths so that a sound pressure, sound intensity or loudness of resulting sound, when output by the sound providers, is at least substantially the same during that/those period(s) of time. This sound pressure/intensity or loudness may be a combined sound pressure/intensity, such as at a predetermined position which may be identified to be a central or listening position. This sound pressure/intensity/loudness may be that of the present audio signal (song or the like) or a predetermined test signal, such as a signal with predetermined or known frequency contents, such as a test tone or frequency.

It is noted that smaller variations may be allowed. Thus, “at least substantially the same” may entail the sound pressure/intensity/loudness varying no more than 10%, preferably no more than 5% during the period of time.

In a simple situation, all sound providers are identical and have identical capabilities when converting an electrical signal to audio. Usually, however, the sound providers are quite different, as e.g. their price and size will determine part of their capabilities. Size and price are often of importance when selecting sound providers for a house or car. Such capabilities may be the efficiency or ability to output low frequency or high frequency audio. A lower efficiency will, with the same signal, give a lower intensity/loudness at this frequency, and it may be desired to take this into account.

Another factor which may affect the sound output by a sound provider is its position and angle in relation to the listener. Such factors may also be compensated for by filtering the signal before feeding to the sound provider.

Thus, in a preferred embodiment, the controlling unit comprises information, for at least one sound provider, relating to a relation between a predetermined audio signal strength or intensity input and a resulting sound intensity or sound pressure output, and wherein the intensities or signal strengths output to the pertaining sound provider, during at least one of the periods of time are determined on the basis of the information.

Thus, the signal for this sound provider may be adapted, often called filtered, in order to fit the characteristics of the sound provider, and the system therefore is able to adapt to different types of sound providers.

This sound pressure/intensity/loudness could be determined for a full audio spectrum (such as 20-20,000 Hz or 25-15,000 Hz) or within each of a number of narrower frequency intervals. If the requirement is set within a number of narrower frequency intervals, the deriving of the first/second/third signals from the host signals may be affected. Otherwise, the same loudness, for example, may be obtained by increasing the bass contents, and also reducing the contents of higher frequency contents and thus deviating from the sound defined by the host signals.

In this situation, for example, the above information for at least one sound provider may relate to the relation for a number of frequencies or frequency intervals, and where, during the second and/or third period of time, one or more of the audio signals is adapted by increasing or decreasing intensities or signal strengths within determined frequencies or frequency intervals.

Thus, if one group has or comprises a special purpose sound provider such as a subwoofer, the activation of this group could bring about a removal of all of or a percentage of the low frequency parts of the signals for other sound providers in order to ensure that the loudness at the lower frequencies is still constant during the activation of the subwoofer.

In order to bring about an orderly and desirable experience when driving the system as described above, the positioning of the sound providers can be of importance. Preferably, the first group of sound providers are positioned, in relation to a predetermined listening position and a predetermined forward direction at the listening position, further along the forward direction than the sound providers of the second group. Also, the sound providers of the second group are positioned further along the forward direction than the sound providers of the third group. Then, the virtual positioning of the sound providers of the second and third groups is from the front to the back when positioned at the listening position facing the listening direction.

Any subwoofer may be positioned more freely, as the human ability to determine the direction of sound is very impaired at the low frequencies.

The listener will experience the sound providers (virtually) as coming from a forward direction and moving toward and around the person to the desired or selected positions, when the left sound providers and right sound providers are operated similarly. Thereafter, the sound may be provided as usual in the surround sound setup used.

Naturally, the opposite “movement” may be used, such as when turning of the system, whereby the second and optionally third sound providers virtually may move along the listening direction and away from the listener so as to give the impression that the audio leaves the surroundings of the listener. Finally, all audio signals may fade if desired.

In correspondence with the second aspect, the invention also relates to, in a third aspect, a system comprising a first and a second group of sound providers, the first and second groups being non-overlapping, and a controlling unit adapted to provide a host audio signal for each of the sound providers,

the controlling unit being adapted to:
during a first period of time, generate an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, simultaneously:
generate the individual first signal for each of the sound providers of the first group,
generate an individual second signal for each of the selected sound provider(s) of the second group, at least one of the second signal(s) being based on at least the host audio signal for the pertaining sound provider of the second group,
   wherein a ratio between:
the signal strength or intensity, in the at least one second signal, of the host audio signal for the pertaining sound provider of the second group and
the signal strength or intensity, in the at least one first signal, of the host audio signal for the selected sound provider(s) of the second group
   increases during the second period of time.

Naturally, all the above definitions and contemplations are equally suitable for this aspect of the invention.

The controller may again be one or more pieces of hardware, such as filters, amplifiers, audio signal providers (antennas, CDROM/DVD/BlueRay/MP3/MP4 players or the like), equalizers or the like. Naturally, all these elements may be assembled into a single processor, FPGA, DSP or the like or may be divided in any manner desirable. Also, the elements may be positioned in the vicinity of each other or may be divided and spread over an area, a network, the www or the like, as desired.

A sound provider usually is a loudspeaker, which may itself be one or more speakers in order to obtain a desired sound output characteristic (tweeter, mid range speaker and woofer, for example).

A group of sound providers may be a single sound provider or e.g. a group of sound providers. Multiple sound providers may be used for increasing the loudness output or in order to have the sound providers together output a desired sound characteristic.

It is usually desired but not required that all groups of sound providers are full range sound providers able to output sound in the frequency range of 20 Hz to 15 kHz.

In one embodiment, the system also comprises a third group of sound providers, the first, second and third groups being non-overlapping, the controlling unit being adapted to:

during the first period of time, base the at least one of the first signal(s) also on the host audio signal for one or more selected sound provider(s) of the third group,
during the second period of time, base the at least one second signal also on the host audio signal for one or more of the selected sound provider(s) of the third group,
wherein a ratio between:
the signal strength or intensity, in the at least one second signal, of the host audio signal for the selected sound provider of the third group and
the signal strength or intensity, in the at least one first signal, of the host audio signal for the selected sound provider(s) of the third group
   increases during the second period of time,
   during a third period of time, subsequently to the second period of time, simultaneously:
generate the individual second signal(s), the second signal(s) being based on at least the host audio signal for the pertaining sound provider of the second group and the host audio signal for one or more of the selected sound provider(s) of the third group, and

generate an individual third signal for each of the selected sound provider(s) of the third group, at least one of the third signal(s) being based on at least the host audio signal for the pertaining sound provider of the third group,

wherein a ratio of:
the signal strength or intensity, in the at least one third signal, of the host audio signal for the selected sound provider(s) of the third group and
a signal strength or intensity, in the at least one second signal, of the host audio signal for the pertaining sound provider of the third group
   increases during the third period of time.

In that or another embodiment, the controlling unit is also adapted to, during the second period of time, generate the individual third signal(s) for each of the selected sound provider(s) of the third group, at least one of the third signal(s) being based on at least the host audio signal for the pertaining sound provider of the third group,

wherein a ratio between:
the signal strength or intensity, in the at least one third signal, of the host audio signal for the pertaining sound provider of the third group and
the signal strength or intensity, in the at least one first signal, of the host audio signal for the selected sound provider(s) of the third group
   increases during the third period of time.

A fourth aspect of the invention relates to a system comprising a first and a second group of sound providers, the first and second groups being non-overlapping, and a controlling unit adapted to provide a host audio signal for each of the sound providers and to:

during a first period of time, generate an individual first signal for each of the sound providers of the first group, at least one of the first signal(s) being based on at least the host audio signal for the pertaining sound provider of the first group and the host audio signal for one or more selected sound provider(s) of the second group,

during a second period of time, subsequently to the first period of time, simultaneously:
generate the individual first signal for each of the sound providers of the first group, the signal strength or intensity, in the at least one first signal, of the host audio signal for the selected sound provider(s) of the second group decreasing during the second period of time and
generate an individual second signal for each of the selected sound provider(s) of the second group, at least one of the second signal(s) being based on at least the host audio signal for the pertaining sound provider of the second group, a signal strength or intensity, in the at least one second signal, of the host audio signal for the pertaining sound provider of the second group, increasing during the second period of time.

Preferably, the system also comprises a third group of sound providers, the first, second and third groups being non-overlapping, the controlling unit being adapted to:

during the first period of time, base the at least one of the first signal(s) also on the host audio signal for one or more selected sound provider(s) of the third group,
during the second period of time:
decrease the signal strength or intensity, in the at least one first signal, of the host audio signal for the selected sound provider(s) of the third group,
base the at least one of the second signal(s) also on at least the host audio signal for one or more of the selected sound provider(s) of the third group, a signal strength or intensity, in the at least one second signal, of the host audio signal for the pertaining sound provider of the third group increasing during the second period of time and
   during a third period of time, subsequently to the second period of time, simultaneously:
generate the individual second signal for each of the sound providers of the second group, the signal strength or intensity, in the at least one second signal, of the host audio signal for the pertaining sound provider(s) of the third group decreasing during the third period of time and
generate an individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group increasing during the third period of time.

In that or another embodiment, the controlling unit is adapted to generate, during the second period of time, the individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group, increasing during the second period of time.

In one embodiment, the controlling unit is further adapted to receive a volume indication and to, during the first, second and/or third period of time, amplify the first, second and optionally third signals by a factor relating to the volume indication.

In one embodiment, the controlling unit is adapted to feed the first, second and optionally third signals to the sound providers of the first, second and optionally third groups and wherein, during the second and/or third period of time, the controlling unit is adapted to output the intensities or signal strengths so that a loudness of a sound output by the sound providers is at least substantially the same during the second and/or third period of time.

In that or another embodiment, the controlling unit comprises information, for at least one sound provider, relating to a relation between a predetermined audio signal strength or intensity input and a resulting sound intensity or sound pressure output, and wherein the controlling unit is adapted to determine and output intensities or signal strengths to the pertaining sound provider during at least one of the periods of time and on the basis of the information.

Then, the information for at least one sound provider may relate to the relation for a number of frequencies or frequency intervals, and where, during the second and/or third period of time, the controlling unit is adapted to adapt one or more of the audio signals by increasing or decreasing intensities or signal strengths within determined frequencies or frequency intervals.

In one embodiment, the first group of sound providers are positioned, in relation to a predetermined listening position and a predetermined forward direction at the listening position, further along the forward direction than the sound providers of the second and/or third group.

In the following, preferred embodiments of the invention are described with reference to the drawing, wherein:

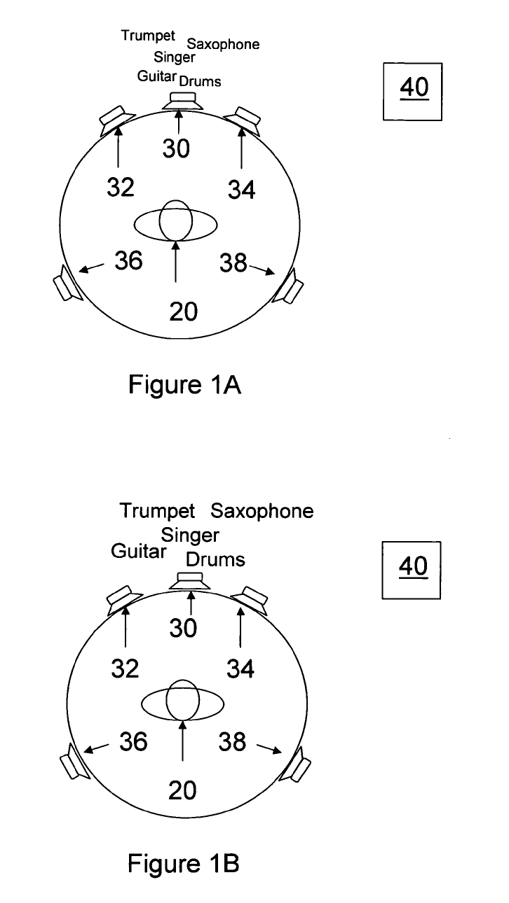

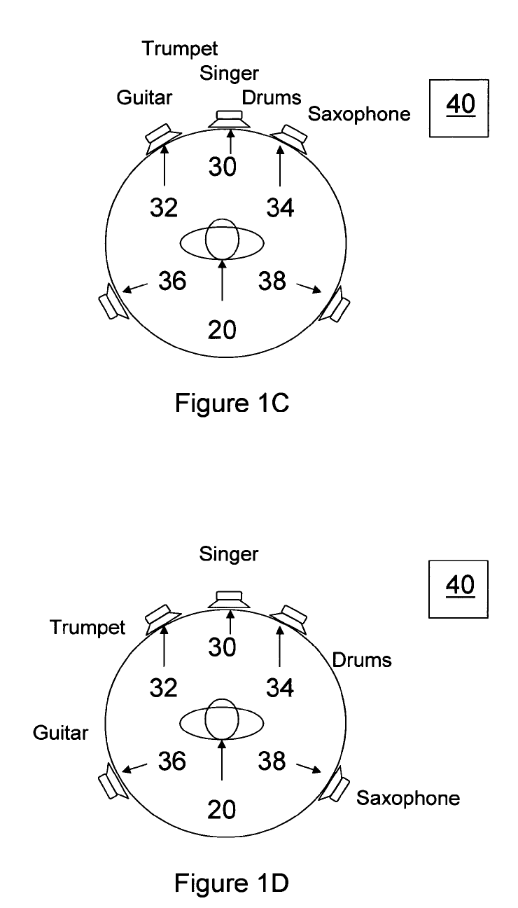

FIG. 1 illustrates virtual movement of signal sources,

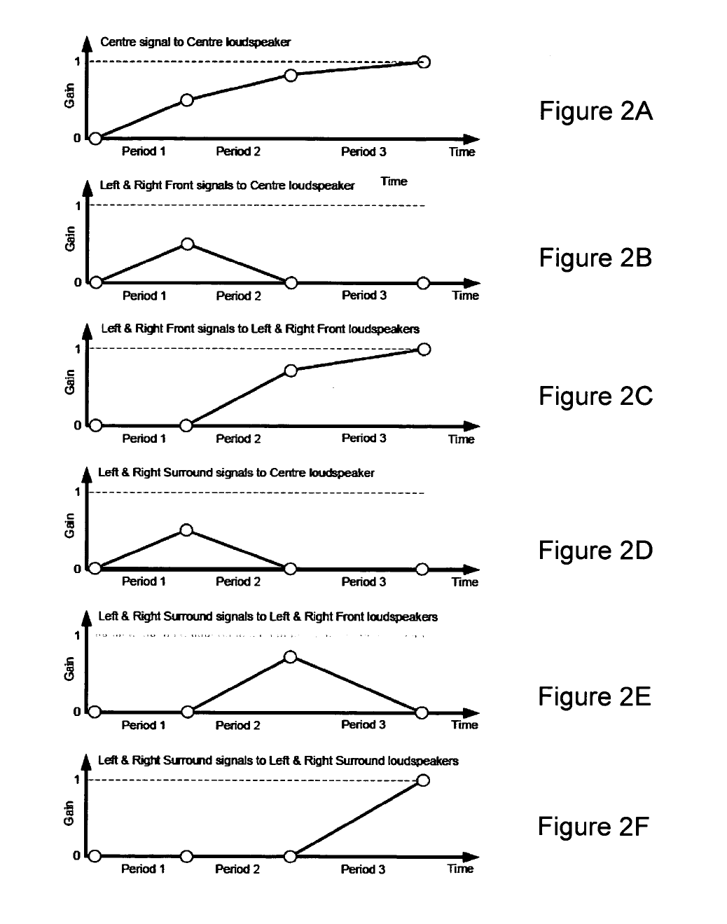

FIG. 2 illustrates gain curves of signals for the individual speakers.

In FIG. 1, turning on an audio system and subsequently virtually moving the signal sources from an initial position to their final, intended positions is illustrated in four illustrations 1A-1D.

In FIG. 1, the audio signal comprises the sounds of drums, a guitar, a saxophone, a trumpet and a singer. In a usual stereo signal, these different sounds are positioned in different locations along the left-to-right axis between two stereo speakers so as to give the listener the impression that persons playing these instruments (or singing) are actually positioned at different locations in front of the listener.

In FIG. 1, a listener 20 is positioned in relation to an audio system comprising a total of 5 speakers or sound providers 30, 32, 34, 36 and 38, where the speakers 32 and 34 are positioned as standard stereo speakers, where the speaker 30 is positioned in front of the listener 20 and where two back speakers 36 and 38 are positioned behind and to the sides of the listener 20 when facing in the listening direction toward speaker 30.

When providing a surround sound signal for more than two speakers, such as 5 speakers as illustrated in the figure, the audio signal either is provided with individual parts or host signals for each speaker or needs to be processed in order to generate the desired host signals for the speakers 30, 36 and 38. Generating, as the skilled person is well aware, the signal for the speaker 30 may be obtained by summing the signals for the speakers 32 and 34, and the signal for e.g. the speaker 36 is obtained by focusing on the differences between the signals of speaker 32 and 34. This is a standard method used in many surround sound systems today.

In FIG. 1A, the system has just been turned on, and an audio signal with increasing strength is fed only to speaker 30, hence the greyed-out instruments.

In FIG. 1B, the audio has been turned up to a given level but is still only provided to the speaker 30.

In FIG. 1C, the speakers 32 and 34 are operated, and it is seen that the signal provided to these speakers are those comprising the saxophone and the guitar, whereas the drums and trumpet virtually are generated at positions between the speakers 34 and 30 and 32 and 30, respectively.

In FIG. 1D, also the speakers 36 and 38 are operated, so that the saxophone sound may be provided behind the speaker 34 and actually at the position of the speaker 38 and the guitar may be represented at a position between the speakers 32 and 36 by, as the skilled person knows, providing the guitar sound by both the speaker 32 and the speaker 36.

In all instances, the position of the singer is at the centre in front of the listener, as is often the case.

In general, the relative positions, along the periphery of the circle, of the instruments will be that along a line between the left and right speakers of the stereo signal. Thus, the stereo perspective is simply widened and, in this embodiment, curved around the person 20.

Thus, when starting up the system, the sound will firstly increase in strength and subsequently widen out from a frontal position to embrace the listener 20 in order to obtain its desired surround sound effect.

Naturally, when turning of the system 10, the reverse effect may be seen in that the instruments or stereo perspective firstly moves to the front of the listener 20 and finally fades.

The skilled person knows that the virtual positioning of a sound provider may be selected between e.g. two physical speakers 34 and 38 by selecting either a ratio of the signal strength of identical signals output to the two speakers 34/38 and/or by providing a delay in the signal for one of the speakers 34/38. Naturally, this identical (possibly delayed) signal may be superimposed on other signals. Thus, as is illustrated in FIG. 1D, the drum may be virtually positioned between the speakers 34/38 and the saxophone at the speaker 38 by providing the signal representing the saxophone to only the speaker 38 but the signal representing the drum to both speakers 34/38 in a ratio, or with a delay, defining the position of the drum. The human ear will be able to discern the difference of these two instruments even when they are playing simultaneously.

Having understood this effect, the virtual positions of the instruments, or more broadly, the stereo perspective of the sound, may be moved/widened using this effect.

In FIG. 2, this is illustrated as gain curves or signal intensity curves of the host signals intended, during normal operation, for the individual speakers 30-38, when fed to these or other speakers 30-38. As described above, a usual surround sound signal comprises different signals for each speaker 30-38, and during normal operation, each speaker 30-38 is fed only the signal intended there for. However, during startup, this differs as described in the following.

FIG. 2A illustrates the signal strength, in the signal fed to the speaker 30, of the host signal intended for the speaker 30.

FIG. 2B illustrates the signal strength, in the signal fed to the speaker 30, of the host signal intended for the speaker 32. The same curve will apply to the signal strength, in the signal fed to the speaker 30, of the host signal intended for the speaker 34.

FIG. 2C illustrates the signal strength, in the signal fed to the speaker 32, of the host signal intended for the speaker 32. The same curve will apply to the signal strength, in the signal fed to the speaker 34, of the host signal intended for the speaker 34.

FIG. 2D illustrates the signal strength, in the signal fed to the speaker 30, of the host signal intended for the speaker 36. The same curve will apply to the signal strength, in the signal fed to the speaker 30, of the host signal intended for the speaker 38.

FIG. 2E illustrates the signal strength, in the signal fed to the speaker 32, of the host signal intended for the speaker 36. The same curve will apply to the signal strength, in the signal fed to the speaker 34, of the host signal intended for the speaker 38.

FIG. 2F illustrates the signal strength, in the signal fed to the speaker 36, of the host signal intended for the speaker 36. The same curve will apply to the signal strength, in the signal fed to the speaker 38, of the host signal intended for the speaker 38.

Thus, during period 1, the centre speaker 30 will be fed a signal with increasing signal strengths of the signals intended for speakers 30, 32, 34, 36 and 38, while no signal is fed to any of speakers 32-38. Thus, if no other signals are fed to the speakers, the overall volume or loudness of the audio is increased during period 1.

During period 2, speakers 32 and 34 are activated and will receive a signal with an increasing intensity of the signals intended for these speakers (FIG. 2C). At the same time, the signal fed to the speaker 30 has the signal strength of the host signal parts thereof intended for the speakers 32 and 34 reduced (FIG. 2B). Also, the signals fed to speakers 32 and 34 will have an increasing intensity of the host signals intended for the speakers 36 and 38, respectively (FIG. 2E). At the same time, the signal fed to the speaker 30 has the signal strength of the parts thereof intended for the speakers 36 and 38 reduced (FIG. 2D).

The function of this period is to have the sound intended for the speakers 32/34 gradually move from the position of the speaker 30 to the positions of the speakers 32/34, which will be the situation when the ratio between the signal strengths of these signals changes. Also, the sound intended for the speakers 36/38 is moved from the position of the speaker 30 to the positions of the speakers 32/34, which will be the situation when the ratio between the signal strengths of these signals changes. After this, the speaker 30 will essentially be fed only the signal intended for that speaker 30.

During period 3, speakers 36 and 38 are activated and will receive a signal with an increasing intensity of the host signals intended for these speakers (FIG. 2F). At the same time, the signal fed to the speakers 32 and 34 have the signal strengths of the host signal parts thereof intended for the speakers 36 and 38 reduced (FIG. 2E). Thus, during this period, the “virtual sound providers 36/38” are virtually moved from the positions of speakers 32/34 to those of speakers 36/38.

An alternative to this may be to already activate speakers 36 and 38 during period 2 and feed a signal comprising the host signal intended for these speakers, where this signal increases in signal strength, during this period of time. The effect of this is, as the signals for the speakers 32/34 also comprises a part of the signals for the speakers 36/38, respectively, that the speakers 36/38 virtually, during period 2, will be positioned at a position between speakers 32/24 and 36/38. Then, during period 3, the part, in the signals for the speakers 32/34, of the signals intended for the speakers 36/38 is reduced, and the signals for the speakers 36/38 is increased, the virtual position of the speakers 36/38 moves toward the actual positions of the speakers 36/38.

It is noted that during period 3, for example, the signal intensities or loudness of the signals intended to e.g. the speaker 32 and fed to the speaker 32 may increase, as is the case for the signal intended for and fed to speaker 30 in period 2 and period 3. In this manner, it may be obtained that the overall loudness provided by all speakers 30-38 is the same during period 2 and 3 as well as after period 3, i.e. during normal operation. Thus, the slopes of the increasing/decreasing signal intensities or gains during periods 2 and 3 as well as the actual gains or signal strengths obtained may be adapted to each other to provide the experience to the listener 20 that the sound, during period 1, increases in strength/loudness and, during period 2 and period 3 merely moves around the person to obtain the final surround sound experience or sound without any significant increase or decrease in signal strength/loudness during these periods of time.

Naturally, the above-described signals for the individual speakers may not merely be amplified in accordance with the gain curves. It may also be desired to actually filter the individual signals over time.

In one situation, one or more of the speakers 30-38 or an additional (not illustrated) speaker may have a frequency characteristic or an output characteristic different from a standard full range speaker and upon the operation of which the overall frequency content output will be altered, if the frequency contents of the sound output by (and thus the signals fed to) the remaining speakers is altered.

In a typical example, a subwoofer is used. Before operating the subwoofer (if operated during period 2, 3 or even later), the signals fed to the operated or active speakers will handle the lower frequency part of the sound output. However, when operating the subwoofer, the lower frequency contents of the signals fed to the remaining speakers may be reduced, such as by filtering the signals, so that the sound output in general has the desired frequency characteristics. If this filtering is not performed, the lower frequency loudness or signals amplitude may be too high. Thus, if the subwoofer is operated from the beginning (during period 1, for example), the same filtering may be used during periods 2 and 3, and during normal operation, for removing/reducing the lower frequency contents of the signals for the other speakers. Alternatively, if the subwoofer is operated only during period 2, 3 or later, this filtering will be enabled at that point in time, and a gradual reduction of the lower frequency contents of the signals fed to the other speakers may be carried out while gradually increasing the signal strength fed to the subwoofer.

Naturally, the speakers 30-38 may have differing frequency output characteristics between themselves or even depending on the strength/intensity of the signals fed thereto. In general, the signal provider/processor 40 may hold information relating to each speaker 30-38 relating to a relation between input signal and output sound (over one or more frequencies or frequency bands), in order for the processor 40 to be able to tailor the signal for each speaker on the basis of this information. Then, the signal output to two speakers may be different even when the signals intended for the speakers are identical in order for the sounds output by the speakers to be identical.

1.-22. (canceled)

23. A method of operating a system comprising a first and a second group of sound providers, the first and second groups being non-overlapping, and a controlling unit adapted to provide a host audio signal for each of the sound providers,
the method comprising:
during a first period of time, the controlling unit generating an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, the controlling unit simultaneously:
generating the individual first signal for each of the sound providers of the first group,
generating an individual second signal for each of the selected sound provider(s) of the second group, at least one of the second signal(s) being based on at least the host audio signal for the pertaining sound provider of the second group,
wherein a ratio between:
the signal strength or intensity, in the at least one second signal, of the host audio signal for the pertaining sound provider of the second group and
the signal strength or intensity, in the at least one first signal, of the host audio signal for the selected sound provider(s) of the second group
increases during the second period of time
wherein the steps performed during the first and second periods of time take place automatically upon initiation of the system.

24. A method according to claim 23, wherein the system comprises further a third group of sound providers, the first, second and third groups being non-overlapping, wherein:
during the first period of time, the at least one of the first signal(s) is based further the host audio signal for one or more selected sound provider(s) of the third group,
during the second period of time, the at least one second signal is based further on the host audio signal for one or more of the selected sound provider(s) of the third group,
wherein a ratio between:
the signal strength or intensity, in the at least one second signal, of the host audio signal for the selected sound provider(s) of the third group and
the signal strength or intensity, in the at least one first signal, of the host audio signal for the selected sound provider(s) of the third group
increases during the second period of time,
during a third period of time, subsequently to the second period of time, the controlling unit simultaneously:
generates the individual second signal(s), at least one of the second signal(s) being based further on and one or more of the selected the host audio signal(s) for the sound provider(s) of the third group, and
generating an individual third signal for each of the selected sound provider(s) of the third group, at least one of the third signal(s) being based on at least the host audio signal for the pertaining sound provider of the third group,
wherein a ratio of:
the signal strength or intensity, in the at least one third signal, of the host audio signal for the selected sound provider(s) of the third group and
a signal strength or intensity, in the at least one second signal, of the host audio signal for the pertaining sound provider of the third group
increases during the third period of time.

25. A method according to claim 23, wherein, during the second period of time, the controlling unit further generates the individual third signal(s) for each of the selected sound provider(s) of the third group, at least one of the third signal(s) being based on at least the host audio signal for the pertaining sound provider of the third group,
wherein a ratio between:
the signal strength or intensity, in the at least one third signal, of the host audio signal for the pertaining sound provider of the third group and
the signal strength or intensity, in the at least one first signal, of the host audio signal for the selected sound provider(s) of the third group
increases during the third period of time.

26. A method of operating a system comprising a first and a second group of sound providers, the first and second groups being non-overlapping, and a controlling unit adapted to provide a host audio signal for each of the sound providers,
the method comprising:
during a first period of time, the controlling unit generating an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, the controlling unit simultaneously:
generating the individual first signal for each of the sound providers of the first group, the signal strength or intensity, in the at least one first signal, of the host audio signal for the selected sound provider(s) of the second group decreasing during the second period of time and
generating an individual second signal for each of the selected sound provider(s) of the second group, at least one of the second signal(s) being based on at least the host audio signal for the pertaining sound provider of the second group, a signal strength or intensity, in the at least one second signal, of the host audio signal for the pertaining sound provider of the second group increasing during the second period of time,
wherein steps performed during the first and second periods of time automatically take place upon initiation of the system.

27. A method according to claim 26, wherein the system comprises further a third group of sound providers, the first, second and third groups being non-overlapping, wherein:
during the first period of time, the at least one of the first signal(s) is based further the host audio signal for one or more selected sound provider(s) of the third group,
during the second period of time:
the signal strength or intensity, in the at least one first signal, of the host audio signal for the selected sound provider(s) of the third group decreases,
the at least one of the second signal(s) is based further on the host audio signal for one or more of the selected sound provider(s) of the third group, a signal strength or intensity, in the at least one second signal, of the host audio signal for the pertaining sound provider(s) of the third group increasing during the second period of time and
during a third period of time, subsequently to the second period of time, the controlling unit simultaneously:
generating the individual second signal for each of the sound providers of the second group, the signal strength or intensity, in the at least one second signal, of the host audio signal for the pertaining sound provider(s) of the third group decreasing during the third period of time and
generating an individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group, increasing during the third period of time.

28. A method according to claim 26, wherein the controlling unit generates, during the second period of time, the individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group, increasing during the second period of time.

29. A method according to claim 23, further comprising the step of the controlling unit receiving a volume indication, wherein, during the first and second periods of time, the first and second signals are amplified by a factor relating to the volume indication.

30. A method according to claim 26, further comprising the step of the controlling unit receiving a volume indication, wherein, during the first and second periods of time, the first and second signals are amplified by a factor relating to the volume indication

31. A method according to claim 23, wherein the first and second signals are fed to the sound providers of the first and second groups and wherein, during the second and/or third periods of time, the controlling unit outputs the intensities or signal strengths so that a loudness of a sound output by the sound providers is at least substantially the same during the second period of time.

32. A method according to claim 26, wherein the first and second signals are fed to the sound providers of the first and second groups and wherein, during the second and/or third periods of time, the controlling unit outputs the intensities or signal strengths so that a loudness of a sound output by the sound providers is at least substantially the same during the second period of time.

33. A method according to claim 23, wherein the controlling unit comprises information, for at least one sound provider, relating to a relation between a predetermined audio signal strength or intensity input and a resulting sound intensity or sound pressure output, and wherein the intensities or signal strengths output to the pertaining sound provider, during at least one of the periods of time are determined on the basis of the information.

34. A method according to claim 26, wherein the controlling unit comprises information, for at least one sound provider, relating to a relation between a predetermined audio signal strength or intensity input and a resulting sound intensity or sound pressure output, and wherein the intensities or signal strengths output to the pertaining sound provider, during at least one of the periods of time are determined on the basis of the information.

35. A system comprising a first and a second group of sound providers, the first and second groups being non-overlapping, and a controlling unit adapted to provide a host audio signal for each of the sound providers,
the controlling unit being adapted to:
during a first period of time, generate an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, simultaneously:
generate the individual first signal for each of the sound providers of the first group,
generate an individual second signal for each of the selected sound provider(s) of the second group, at least one of the second signal(s) being based on at least the host audio signal for the pertaining sound provider of the second group,
wherein a ratio between:
the signal strength or intensity, in the at least one second signal, of the host audio signal for the pertaining sound provider of the second group and
the signal strength or intensity, in the at least one first signal, of the host audio signal for the selected sound provider(s) of the second group
increases during the second period of time,
wherein the controlling unit is adapted to perform the steps of the first and second periods of time automatically upon start-up of the system.

36. A system according to claim 35, further comprising a third group of sound providers, the first, second and third groups being non-overlapping, the controlling unit being adapted to:
during the first period of time, base the at least one of the first signal(s) further on the host audio signal for one or more selected sound provider(s) of the third group,
during the second period of time, base the at least one second signal further on the host audio signal for one or more of the selected sound provider(s) of the third group,
wherein a ratio between:
the signal strength or intensity, in the at least one second signal, of the host audio signal for the selected sound provider of the third group and
the signal strength or intensity, in the at least one first signal, of the host audio signal for the selected sound provider(s) of the third group
increases during the second period of time,
during a third period of time, subsequently to the second period of time, simultaneously:
generate the individual second signal(s), the second signal(s) being based on at least the host audio signal for the pertaining sound provider of the second group and the host audio signal for one or more of the selected sound provider(s) of the third group, and
generate an individual third signal for each of the selected sound provider(s) of the third group, at least one of the third signal(s) being based on at least the host audio signal for the pertaining sound provider of the third group,
wherein a ratio of:
the signal strength or intensity, in the at least one third signal, of the host audio signal for the selected sound provider(s) of the third group and
a signal strength or intensity, in the at least one second signal, of the host audio signal for the pertaining sound provider of the third group
increases during the third period of time.

37. A system according to claim 35, wherein the controlling unit is further adapted to, during the second period of time, generate the individual third signal(s) for each of the selected sound provider(s) of the third group, at least one of the third signal(s) being based on at least the host audio signal for the pertaining sound provider of the third group,
wherein a ratio between:
the signal strength or intensity, in the at least one third signal, of the host audio signal for the pertaining sound provider of the third group and
the signal strength or intensity, in the at least one first signal, of the host audio signal for the selected sound provider(s) of the third group
increases during the third period of time.

38. A system comprising a first and a second group of sound providers, the first and second groups being non-overlapping, and a controlling unit adapted to provide a host audio signal for each of the sound providers and to:
during a first period of time, generate an individual first signal for each of the sound providers of the first group, at least one of the first signal(s) being based on at least the host audio signal for the pertaining sound provider of the first group and the host audio signal for one or more selected sound provider(s) of the second group,
during a second period of time, subsequently to the first period of time, simultaneously:
generate the individual first signal for each of the sound providers of the first group, the signal strength or intensity, in the at least one first signal, of the host audio signal for the selected sound provider(s) of the second group decreasing during the second period of time and
generate an individual second signal for each of the selected sound provider(s) of the second group, at least one of the second signal(s) being based on at least the host audio signal for the pertaining sound provider of the second group, a signal strength or intensity, in the at least one second signal, of the host audio signal for the pertaining sound provider of the second group, increasing during the second period of time,
wherein the controlling unit is adapted to perform the steps of the first and second periods of time automatically upon start-up of the system.

39. A system according to claim 38, further comprising a third group of sound providers, the first, second and third groups being non-overlapping, the controlling unit being adapted to:
during the first period of time, base the at least one of the first signal(s) further on the host audio signal for one or more selected sound provider(s) of the third group,
during the second period of time:
decrease the signal strength or intensity, in the at least one first signal, of the host audio signal for the selected sound provider(s) of the third group,
base the at least one of the second signal(s) further on at least the host audio signal for one or more of the selected sound provider(s) of the third group, a signal strength or intensity, in the at least one second signal, of the host audio signal for the pertaining sound provider of the third group increasing during the second period of time and
during a third period of time, subsequently to the second period of time, simultaneously:
generate the individual second signal for each of the sound providers of the second group, the signal strength or intensity, in the at least one second signal, of the host audio signal for the pertaining sound provider(s) of the third group decreasing during the third period of time and
generate an individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group increasing during the third period of time.

40. A system according to claim 38, wherein the controlling unit is adapted to generate, during the second period of time, the individual third signal for each of the selected sound provider(s) of the third group, at least one of the third signal(s) being based on at least the host audio signal for the pertaining sound provider of the third group, a signal strength or intensity, in the at least one third signal, of the host audio signal for the pertaining sound provider of the third group, increasing during the second period of time.

41. A system according to claim 35, wherein the controlling unit is further adapted to receive a volume indication and to, during the first and second period of time, amplify the first and second signals by a factor relating to the volume indication.

42. A system according to claim 38, wherein the controlling unit is further adapted to receive a volume indication and to, during the first and second period of time, amplify the first and second signals by a factor relating to the volume indication.

43. A system according to claim 35, wherein the controlling unit is adapted to feed the first and second third signals to the sound providers of the first and second groups and wherein, during the second period of time, the controlling unit is adapted to output the intensities or signal strengths so that a loudness of a sound output by the sound providers is at least substantially the same during the second period of time.

44. A system according to claim 38, wherein the controlling unit is adapted to feed the first and second third signals to the sound providers of the first and second groups and wherein, during the second period of time, the controlling unit is adapted to output the intensities or signal strengths so that a loudness of a sound output by the sound providers is at least substantially the same during the second period of time.

45. A system according to claim 35, wherein the controlling unit comprises information, for at least one sound provider, relating to a relation between a predetermined audio signal strength or intensity input and a resulting sound intensity or sound pressure output, and wherein the controlling unit is adapted to determine and output intensities or signal strengths to the pertaining sound provider during at least one of the periods of time and on the basis of the information.

46. A system according to claim 38, wherein the controlling unit comprises information, for at least one sound provider, relating to a relation between a predetermined audio signal strength or intensity input and a resulting sound intensity or sound pressure output, and wherein the controlling unit is adapted to determine and output intensities or signal strengths to the pertaining sound provider during at least one of the periods of time and on the basis of the information.
